(19) United States
(12) Patent Application Publication
(10) Pub. No.: US 2011/0242746 A1
(43) Pub. Date: Oct. 6, 2011

(54) DILATANT ENCLOSURE SYSTEMS AND METHODS

(75) Inventors: Dustin L. Hoffman, Cypress, TX (US); Britt C. Ashcraft, Tomball, TX (US); William Adam Gralewski, Houston, TX (US)

(73) Assignee: HEWLETT-PACKARD DEVELOPMENT COMPANY, L. P., HOUSTON, TX (US)

(21) Appl. No.: 12/753,084

(22) Filed: Apr. 1, 2010

(51) Int. Cl. G06F 1/16; H05K 7/00; H05K 5/00; H05K 7/20; H05K 3/00

(52) U.S. Cl. 361/679.02; 361/679.01; 361/752; 361/694; 29/829

(57) ABSTRACT

Dilatant enclosure systems and methods are provided. A dilatant enclosure system can include an open framework; an electronic device disposed at least partially within the open framework; and a breathable, dilatant material covering at least a portion of the open framework. A dilatant enclosure method can include at least partially covering an open framework with a breathable, dilatant fabric material. The method can further include disposing an electronic device at least partially within the open framework.

### BACKGROUND

The ever increasing demand for additional processor speed, greater graphics capabilities, and high-speed communications capabilities in portable electronic devices has resulted in an ever increasing component density within such devices. Frequently, the portable device is partially or completely housed in a single or multi-piece, rigid, exterior enclosure, shell, or case, to protect the internal electronic components. While such rigid enclosures may serve to protect the electronic components disposed within, such enclosures frequently provide only limited ventilation capability, for example via slots disposed on a portion of the enclosure. Additionally, it is often difficult to reduce the weight of and/or to impart an ergonomic feel to a rigid case or enclosure, leading to consumer dissatisfaction with the available selection of enclosures on the market.

### BRIEF DESCRIPTION OF THE DRAWINGS

Advantages of one or more disclosed embodiments may become apparent upon reading the following detailed description and upon reference to the drawings in which:

FIG. 1 is an upper perspective view depicting one example of a dilatant enclosure system, according to one or more embodiments described herein;

FIG. 1A is a partial sectional view depicting one example of the dilatant enclosure system depicted in FIG. 1, according to one or more embodiments described herein;

FIG. 2 is a sectional view depicting one example of another dilatant enclosure system, according to one or more embodiments described herein;

FIG. 3 is a flow diagram depicting one example of a dilatant enclosure method, according to one or more embodiments described herein; and

FIG. 4 is a flow diagram depicting one example of another dilatant enclosure method, according to one or more embodiments described herein.

### DETAILED DESCRIPTION

Dilatant materials define a class of materials that incorporate or are based upon one or more non-Newtonian fluids. Dilatant materials can include the class of materials known as “shear thickening” materials, which include any material in which viscosity increases with the rate of shear. While dilatant materials can be soft, pliable, and flexible under normal circumstances, one property common amongst dilatant materials is the ability of the material to assume a near instantaneous rigid shape when subjected to a sudden impact or shearing force. Dilatant materials can be incorporated into non-porous materials, such as a solid rubber-like material, or porous materials, such as a woven fabric-like material. One example of a commercially available dilatant material is D3O™ manufactured by d3o lab (Hove, England, www.d3olab.com).

Portable electronic devices often pack a considerable number of heat generating components within a relatively confined space within a rigid enclosure. The need to properly cool the components and the need to protect the components from damage due to shock, for example if the device happens to slip from a user's grasp, are often at odds with each other. Proper cooling requires considerable number of apertures in the enclosure to facilitate the free flow of air through the device, while proper protection from shock and atmospheric contaminants requires the converse, to with, an enclosure that has few, if any apertures.

The use of a fabric to cover an electronic device provides an advantage in cooling the device due to the relatively free flow of air through the fabric. However, a conventional fabric cover does little to protect the components within the device from damage due to shock. The use of a hard shell, on the other hand, provides significant protection for the components forming the device, frequently while compromising cooling capability. The use of a breathable dilatant fabric can provide the porosity of a fabric during ordinary use of the device, while providing the protection of a rigid or solid enclosure when the device is subjected to a sudden shock or impact.

As used herein, the term “breathable” and materials that are referred to as being “breathable” or having one or more “breathable” characteristics can include any material that permits the passage of a gas, such as air, therethrough.

Dilatant enclosure systems and methods are provided. A dilatant enclosure system can include an open framework; an electronic device disposed at least partially within the open framework; and a breathable, dilatant material covering at least a portion of the open framework. A dilatant enclosure method can include at least partially covering an open framework with a breathable, dilatant fabric material. The method can further include disposing an electronic device at least partially within the open framework.

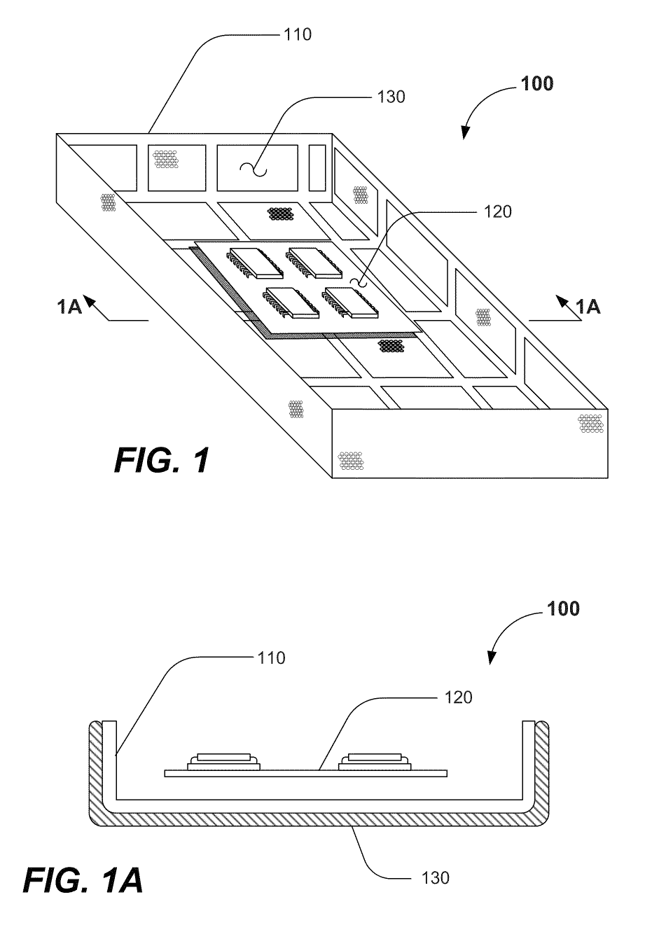

For clarity and ease of discussion, FIGS. 1 and 1A will be discussed in detail together. FIG. 1 is an upper perspective view depicting one example of a dilatant enclosure system 100, according to one or more embodiments. FIG. 1A is a partial sectional view depicting one example of the dilatant enclosure system 100 depicted in FIG. 1, according to one or more embodiments In at least some embodiments, the dilatant enclosure system 100 can include an open framework 110 at least partially surrounding or enclosing an electronic device 120. The open framework 110 can define at least an interior surface and an exterior surface. A breathable, dilatant material 130 can be disposed about at least a portion of the open framework 110. In some embodiments, the breathable, dilatant material 130 can be at least partially disposed about the exterior surface formed by the open framework 110 as depicted in FIG. 1. In other embodiments, the breathable, dilatant material 130 can be at least partially disposed about the interior surface formed by the open framework 110.

The open framework 110 can include any structure suitable for providing a rigid framework or “skeleton” having at least one aperture or perforation therethrough. Although the open framework 110 is depicted in FIGS. 1 and 1A as an open top rectangular structure, any shape, form, or geometry can be used with equal efficacy. In some embodiments, the open framework can include a plurality of connected members as depicted in FIG. 1. The plurality of connected members can include a plurality of metallic members, non-metallic members, composite metallic/non-metallic members, or any combination thereof. The plurality of connected members forming the open framework 110 can be temporarily or permanently connected, for example through the use of one or more removable or non-removable fasteners, adhesives, weldment, or the like. In some embodiments, the open framework 110 can be formed using an integrally formed plurality of members, for example an injection or compression molded plurality of members. In some embodiments, the open framework 110 can be a perforated material such as metal, plastic, or screen, formed or cast in any desired shape or configuration.

In some embodiments, all or a portion of the interior surface, the exterior surface, or both the interior and exterior surfaces of the open framework 110 can be partially or completely covered by a non-breathable material. For example, in some embodiments, the open framework can define a generally rectangular, box shaped member having an open frame bottom and sides and a solid top supporting one or more user interface devices such as a display, keyboard, keypad, pointing device, and the like.

As used herein, the terms “top,” “bottom,” and “sides” and other like terms used herein refer to relative positions to another and are not intended, nor should be interpreted, to denote a particular absolute direction or spatial orientation. For example, a feature described as being on the “bottom” surface of a device could be on the “top” surface or a “side” surface of the device if the device is rotated or inverted; such rotation or inversion is envisioned to be within the scope of one or more claimed embodiments described herein.

In some embodiments, the open framework 110 can include one or more mounting lugs, standoffs, or similar features permitting the disposal or attachment of an electronic device 120 at least partially within the framework. The electronic device 120 can include any number of electrical or electronic systems, electrical or electronic devices, or any combination of electrical or electronic systems and devices. In some embodiments, the electrical device 120 can include one or more heat generating components, for example one or more circuits capable of generating heat as an operational byproduct. In at least some embodiments, the electronic device 120 can include a printed circuit board (“PCB”) disposed at least partially within the open framework 110 having no intervening enclosures disposed between the PCB and the open framework 110. In at least some embodiments, the electronic device 120 can be a laptop computer, a netbook computer, a portable computer, a cellular device, a portable digital assistant, a handheld computer, and a handheld gaming device.

In at least one embodiment, the electronic device 120 can include a computing device, for example a device having at least one processor communicatively coupled to at least one memory module. In some embodiments, the electronic device 120 can include one or more input ports, one or more output ports, or any combination of input and output ports, for example one or more user inputs or input ports (e.g. keyboard, keypad, mouse, and the like), one or more network ports, one or more peripheral ports (e.g. video input ports, video output ports, audio input ports, audio output ports, data input ports, data output ports, and the like). In some embodiments, all or a portion of the electronic device 120 can be externally accessed by a user of the electronic device.

As used herein, the term “communicative coupling”, or a connection by which entities are “communicatively coupled”, is one by which electromagnetic signals, physical communications, and/or logical communications may be sent and/or received. Typically, a communicative coupling includes a physical interface, an electrical interface, and/or a data interface, but it is to be noted that a communicative coupling may include differing combinations of these or other types of connections sufficient to allow intermittent or continuous communication or control. For example, two entities can be communicatively coupled by being able to communicate signals to each other directly or through one or more intermediate entities like a processor, operating system, a logic device, software, or other entity. Logical and/or physical communication channels can be used to create a communicative coupling.

A breathable, dilatant material can be disposed in, on, or about at least a portion of the open framework 110. In at least some embodiments, the breathable, dilatant material 130 can permit the ingress and egress of a cooling fluid such as air into and out of the open framework 110. Such ingress and egress of cooling fluid can assist with the cooling of all or a portion of the electronic device 120 by providing a path for the relatively cool cooling fluid to enter and the relatively warm cooling air to exit by flowing at least partially through the open framework 110 and breathable dilatant material 130.

The breathable dilatant material 130 can be detachably or non-detachably attached to all or a portion of the open framework 110. In at least some embodiments, all or a portion of the breathable, dilatant material 130 can be non-detachably attached to at least a portion of the open framework 110, for example by thermal welding, adhesives, non-removable fasteners, or the like. In at least some embodiments, all or a portion of the breathable, dilatant material 130 can be detachably attached to at least a portion of the open framework 110, for example using removable fasteners, or the like.

In some embodiments, the breathable, a portion of dilatant material 130 can include one or more non-dilatant materials, for example, one or more other fibrous materials intended to provide strength, resiliency, or body to the breathable, dilatant material 130. In some embodiments, the breathable, dilatant material 130 can be applied to the surface of a natural or man-made fiber based fabric. In some embodiments, the breathable, dilatant material 130 can be formed into fibers or similar shape and woven into a natural or man-made fiber based fabric. As used herein, the term “fiber” refers to any structure having a length along a principal axis that exceeds a diameter measured normal to the principal axis.

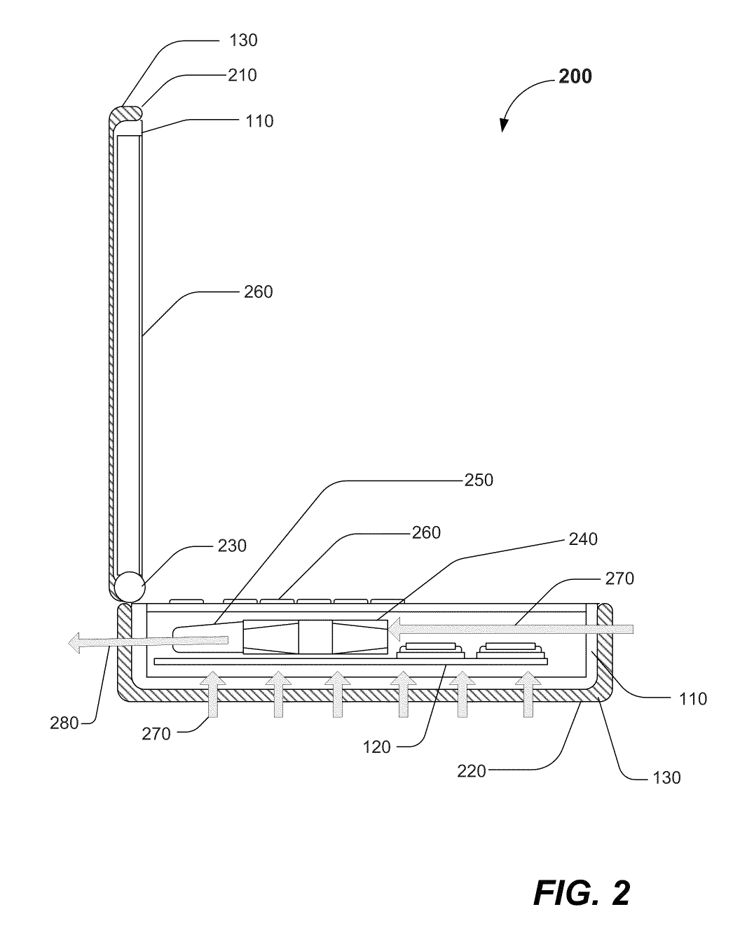

FIG. 2 is a sectional view depicting one example of another enclosure system 200, according to one or more embodiments. In some embodiments, the enclosure system 200 can include a hinged, two-member, clamshell enclosure. In some embodiments, the clamshell enclosure can include a rotatable member 210 and a base member 220 operably connected using at least one hinge 230.

In at least some embodiments, the electronic device 120 can include at least one air mover 240. In some embodiments, the discharge stream from of the air mover 240 can flow across, about, or around one or more heat transfer surfaces 250, for example one or more heat exchangers thermally coupled to one or more heat producing electronic devices. In at least some embodiments, one or more input devices, one or more output devices, or any combination of input and output devices (collectively “I/O devices”) 260 can be disposed in, on, or about the rotatable member 210, the base member 220, or both the rotatable member 210 and the base member 220.

Cool inlet air 270 can enter the rotatable member 210, the base member 220, or both the rotatable member 210 and the base member 220 by flowing through all or a portion of the breathable dilatant material 130. Warm exhaust air 280 can likewise exit the rotatable member 210, the base member 220, or both the rotatable member 210 and the base member 220 by flowing through all or a portion of the breathable dilatant material 130. In at least some embodiments, all or a portion of the air mover 240 exhaust can flow in, around, or about all or a portion of the one or more heat transfer surfaces 250 prior to exiting the base member 220 as exhaust air 280. In at least some embodiments, for example as depicted in FIG. 2, all or a portion of the electronic device 120 can be disposed in such a manner that the cool inlet air 270 can flow in, around, about, or across the device prior to entering the air mover 240.

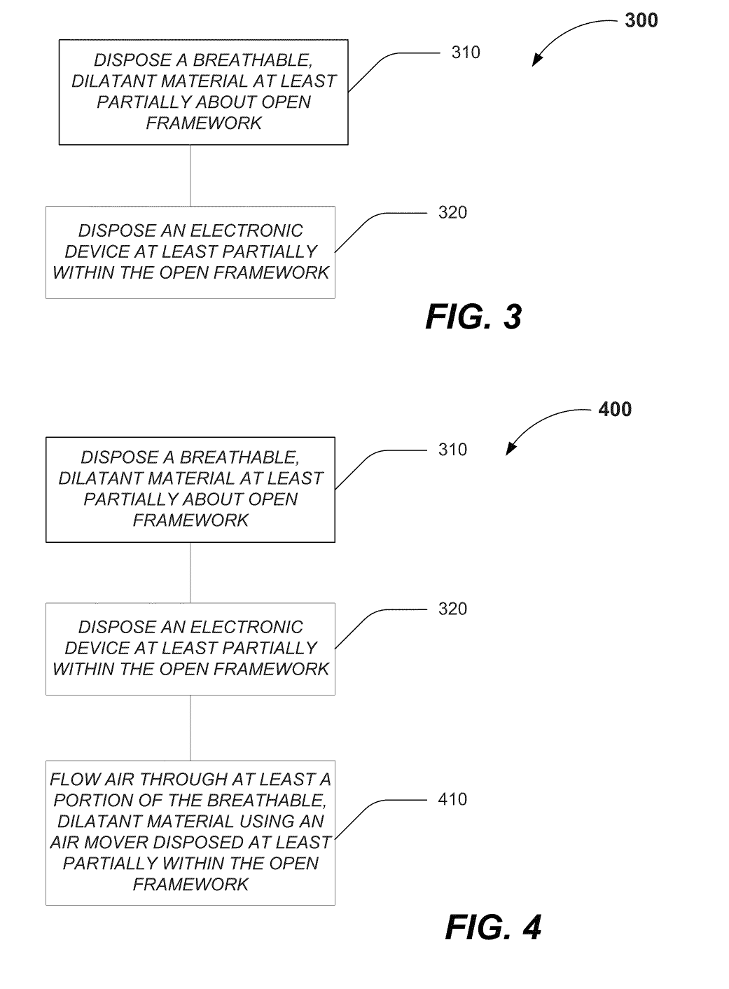

FIG. 3 is a flow diagram depicting one example of a dilatant enclosure method 300, according to one or more embodiments. In at least some embodiments, the dilatant enclosure method 300 can include disposing a breathable dilatant material 130 at least partially about an open framework 110 at 310. The method 300 can also include disposing an electronic device 120 at least partially within the open framework 110 at 320.

FIG. 4 is a flow diagram depicting one example of another dilatant enclosure method 400, according to one or more embodiments. In at least some embodiments, the dilatant enclosure method 400 can include flowing air through at least a portion of the breathable, dilatant material 130 using an air mover 240 disposed at least partially within the open framework 110 at 410.

While the foregoing is directed to embodiments of the present invention, other and further embodiments of the invention may be devised without departing from the basic scope thereof, and the scope thereof is determined by the claims that follow.

What is claimed is:

1. An enclosure system, comprising:
an open framework;
an electronic device disposed at least partially within the open framework; and
a breathable, dilatant material disposed about at least a portion of the open framework.

2. The system of claim 1, wherein the open framework comprises a hinged, two-piece, clamshell enclosure.

3. The system of claim 1, wherein the open framework comprises a perforated metal member.

4. The system of claim 1, wherein the electronic device is selected from the group of electronic devices consisting of: a laptop computer, a netbook computer, a portable computer, a cellular device, a portable digital assistant, a handheld computer, and a handheld gaming device.

5. The system of claim 1, wherein the open framework comprises a plurality of connected members.

6. The system of claim 5, wherein the plurality of connected members comprise a plurality of metallic members.

7. The system of claim 5, wherein the plurality of connected members comprise a plurality of non-metallic members.

8. The system of claim 1, wherein the breathable, dilatant material comprises a fabric containing D3O™.

9. The system of claim 1, wherein the electronic device comprises a printed circuit board (“PCB”) disposed at least partially within the open framework, and wherein no intervening enclosures are disposed between the PCB and the open framework.

10. The system of claim 1, wherein the electronic device comprises an air mover.

11. An enclosure method, comprising:
disposing a breathable, dilatant material at least partially about open framework; and
disposing an electronic device at least partially within the open framework.

12. The method of claim 11, wherein the electronic device comprises a printed circuit board (“PCB”) disposed at least partially within the open framework, and wherein no intervening enclosures are disposed between the PCB and the open framework.

13. The method of claim 11, wherein the open framework comprises a hinged, two-piece, clamshell enclosure.

14. The method of claim 11, wherein the open framework comprises a perforated metal member.

15. The method of claim 11, wherein the open framework comprises a plurality of connected members.

16. The method of claim 15, wherein the plurality of connected members comprise a plurality of metallic members.

17. The method of claim 15, wherein the plurality of connected members comprise a plurality of non-metallic members.

18. The method of claim 11, wherein the breathable, dilatant material comprises a fabric containing D3O™.

19. The method of claim 11, further comprising:
flowing air through at least a portion of the breathable, dilatant material using an air mover disposed at least partially within the open framework.

20. The method of claim 19, wherein at least a portion of the air flowing through the breathable, dilatant material flows about a heat exchange surface.
